(19) United States
(12) Patent Application Publication
(10) Pub. No.: US 2017/0345547 A1
(43) Pub. Date: Nov. 30, 2017

(54) STACKED INDUCTORS

(71) Applicant: QUALCOMM Incorporated, San Diego, CA (US)

(72) Inventor: Miena Armanious, La Jolla, CA (US)

(21) Appl. No.: 15/192,752

(22) Filed: Jun. 24, 2016

Related U.S. Application Data
(60) Provisional application No. 62/342,718, filed on May 27, 2016.

(51) Int. Cl. H01F 27/28; H03H 7/01; H03F 15/00

(52) U.S. Cl. CPC H01F 27/2804; H03F 15/00; H03H 7/0138

(57) ABSTRACT

Exemplary embodiments of the disclosure are related to inductors, e.g., at least a pair of planar inductors for a wireless apparatus, for example transceivers used in a wireless device. A device may include a first planar inductor configured on a first area of a substrate. The first planar inductor includes a first loop configured to produce a first magnetic field in a first direction and a second loop configured to produce a second magnetic field in a second direction. The device further includes a second planar inductor configured on a second area of the substrate. The second planar inductor includes a third loop configured to produce a third magnetic field in a third direction. The third loop may be configured to surround the first loop and divide the second loop into an enclosed area and an external area.

### CROSS REFERENCE TO RELATED APPLICATIONS

This application claims priority to U.S. Provisional Pat. App. Ser. No. 62/342,718, entitled “STACKED INDUCTORS,” filed May 27, 2016, assigned to the assignee of the present disclosure, the contents of which are hereby incorporated by reference herein in their entirety.

### FIELD

The disclosure relates generally to electronic devices. More specifically, the disclosure includes embodiments related to inductors on a planar substrate.

### BACKGROUND

Planar inductors are commonly used in integrated circuit design. Inductors have varying purposes in circuit design. Specifically, inductors may be used in transmitters and receivers for filters and other matching and tuning circuits. Planar inductors may be formed on substrates that include one or more conductive layers separated by one or more dielectric layers on the substrate. The conductive layers can be used to form circuit components that may be separated by the dielectric layers. As circuits become increasingly more complex, the area that is required to build circuits also increases. As more circuit components are placed closer together, some components may cause interfering fields resulting in undesirable interference. Furthermore, additional circuit components may require additional circuit area on the substrate.

Inductors are commonly used in communication circuits for filtering desired and undesired signals. Implementation of a communication transceiver on a substrate may require many inductors for filtering and matching. Inductors may require a significant portion of the substrate when forming integrated circuits. This reduces the area available to other circuit elements. Furthermore, during operation, current passing through an inductor creates a magnetic field which can couple onto nearby circuit components. In some applications it is desirable to include inductors with low magnetic coupling therebetween. In some implementations, to select levels of coupling between inductors, the spatial separation between the inductors may be varied.

### SUMMARY

Certain embodiments described herein include a device comprising a first inductor and a second inductor. The first inductor may be configured on a first area of a substrate, and may include a first loop and a second loop arranged in a figure-8 configuration. The second inductor may be configured on a second area of the substrate and include a third loop surrounding the first loop and dividing the second loop into an enclosed area and an external area.

Certain embodiments described herein include a method comprising producing first, second, and third magnetic fields in respective conducting loops. The first magnetic field may be produced in a first conducting loop in a first direction. The second magnetic field may be produced in a second conducting loop in a second direction. The third magnetic field may be produced in a third conducting loop in a third direction. The third direction may substantially align with either of the first or the second directions. The third loop may surround or enclose the first loop and bisect the second loop.

Certain embodiments described herein include an apparatus comprising first means for inducting and second means for inducting. The first means for inducting may comprise means for producing a first magnetic field in a first direction and means for producing a second magnetic field in a second direction. The second means for inducting may comprise means for producing a third magnetic field substantially in the first direction or substantially in the second direction. The means for producing the third magnetic field may surround or enclose the means for producing the first magnetic field and bisect the means for producing the second magnetic field.

### BRIEF DESCRIPTION OF THE DRAWINGS

FIG. 1 shows a block diagram of a wireless device that may include several inductors.

FIG. 2 shows a functional diagram of a pair of inductors for a device, in accordance with an embodiment.

FIG. 3 shows an equivalent circuit for an overlapping pair of planar inductors formed on a substrate, in accordance with an embodiment.

FIG. 4A shows a cross-sectional view of an exemplary layout of a pair of planar inductors, in accordance with an embodiment.

FIG. 4B shows a top view of an exemplary layout of a pair of planar inductors, in accordance with an embodiment.

FIG. 5 shows a perspective view of an exemplary layout of a pair of planar inductors, in accordance with an embodiment.

FIG. 6 shows a functional diagram of a pair of inductors for a device, in accordance with another embodiment.

FIG. 7 shows an equivalent circuit for an overlapping pair of planar inductors formed on a substrate, in accordance with another embodiment.

FIG. 8 shows a top view of an exemplary layout of a pair of planar inductors, in accordance with another embodiment.

FIG. 9 shows a perspective view of an exemplary layout of a pair of planar inductors, in accordance with another embodiment.

FIG. 10 is a flowchart illustrating a method, in accordance with one or more exemplary embodiments.

FIG. 11 shows a functional diagram of a pair of inductors for a device, in accordance with an embodiment.

FIG. 12 is a flowchart illustrating a method, in accordance with one or more exemplary embodiments.

FIG. 13 shows a functional diagram of an apparatus including a pair of inductors for a device, in accordance with an embodiment.

### DETAILED DESCRIPTION

The detailed description set forth below in connection with the appended drawings is intended as a description of exemplary embodiments and is not intended to represent the only embodiments in which the present disclosure can be practiced. The term “exemplary” used throughout this description means “serving as an example, instance, or illustration,” and not necessarily as preferred or advantageous over other exemplary embodiments. The detailed description includes specific details for the purpose of providing a thorough understanding of the exemplary embodiments. The exemplary embodiments may be practiced without these specific details. In some instances, well-known structures and devices are shown in block diagram form in order to avoid obscuring the novelty of the exemplary embodiments presented herein.

Inductors are used in a myriad of electronic circuits. Specifically, may be used in filters and matching circuits in transmitters and receivers. An inductor creates a magnetic field in the near and far fields of the inductor. A magnetic field can induce currents in an adjacent second inductor affecting the desired performance of a circuit that incorporates the second inductor. Accordingly, adjacent inductors may be spatially arranged to mitigate interfering induced currents. These interfering induced currents generated by fluxes, may be controlled to generate desirable low magnetic coupling between the inductors. A device or inductor pair with low magnetic coupling provides inductors for both matching and filtering and enables closer fabrication and placement of adjacent inductors in more complex circuits.

Certain embodiments described herein The disclosed aspects of the invention allow vertical stacking of multiple inductors, e.g., planar inductors, that exhibit low magnetic coupling. As defined herein, “planar” may include loops that are formed on multiple layers where portions of the loops may be formed on multiple layers connected by an interconnection such as one or more vias. This may reduce the area required to implement two or more inductors by nearly half. Applications for stacked inductors may include two-stage matching circuits, a circuit including a matching inductor and a choke inductor, a circuit including two choke inductors for different bands, and a circuit including two matching circuit inductors for different bands.

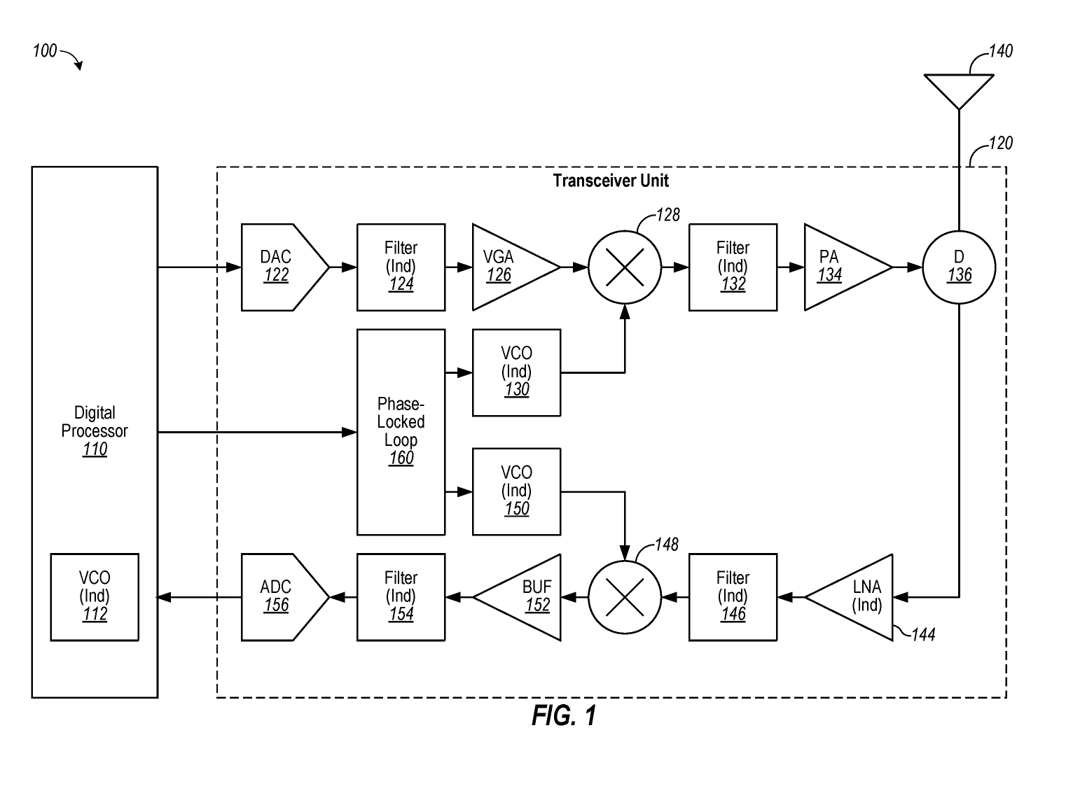

FIG. 1 shows a block diagram of a wireless device 100 that may include several inductors. Certain of these inductors may benefit from low magnetic coupling between adjacent inductors. Specifically, wireless device 100 may be a cellular phone, a personal digital assistant (PDA), a terminal, a handset, a wireless modem, a laptop computer, etc. Wireless device 100 is capable of providing bi-directional communication via a transmit path and a receive path.

On the transmit path, a digital processor 110 may process data to be transmitted and provide a stream of chips to a transceiver unit 120. Within transceiver unit 120, one or more digital-to-analog converters (DACs) 122 may convert the stream of chips to one or more analog signals. The analog signal(s) may be filtered by a filter 124, amplified by a variable gain amplifier (VGA) 126, and frequency upconverted from baseband to RF by a mixer 128 to generate an upconverted signal. The frequency upconversion may be performed based on a transmit local oscillator (LO) signal from a voltage controlled oscillator (VCO) 130. The upconverted signal may be filtered by a filter 132, amplified by a power amplifier (PA) 134, routed through a duplexer (D) 136, and transmitted via an antenna 140.

On the receive path, an RF signal may be received by antenna 140, routed through duplexer 136, amplified by a low noise amplifier (LNA) 144, filtered by a filter 146, and frequency downconverted from RF to baseband by a mixer 148 with a receive LO signal from a VCO 150. The downconverted signal from mixer 148 may be buffered by a buffer (BUF) 152, filtered by a filter 154, and digitized by one or more analog-to-digital converters (ADCs) 156 to obtain one or more streams of samples. The sample stream(s) may be provided to digital processor 110 for processing.

FIG. 1 shows a specific transceiver design. In general, the signal conditioning for each path may be performed with one or more stages of amplifier, filter, and mixer. FIG. 1 shows some circuit blocks that may be used for signal conditioning on the transmit and receive paths. Other designs, however, may be implemented in the device 100. Further, elements illustrated in the transceiver unit 120 may be implemented in separate module, chips, packages, etc. For example, the PA 134 and/or the duplexer 136 may be implemented in a separate chip and/or module from the remaining elements of the transceiver unit 120. Such separate chip and/or module may be coupled to the remaining elements, for example by traces or other means for coupling between modules on a circuit board.

In the design shown in FIG. 1, transceiver unit 120 includes two VCOs 130 and 150 for the transmit and receive paths, respectively. Digital processor 110 includes a high-speed VCO 112 that may generate clocks for various units within processor 110. VCOs 112, 130 and 150 may be implemented with various VCO designs. Each VCO may be designed to operate at a specific frequency or a range of frequencies. For example, VCOs 130 and 150 may be designed to operate at an integer multiple of (e.g., 1, 2, or 4 times) one or more of the following frequency bands—a Personal Communication System (PCS) band from 1850 to 1990 MHz, a cellular band from 824 to 894 MHz, a Digital Cellular System (DCS) band from 1710 to 1880 MHz, a GSM900 band from 890 to 960 MHz, an International Mobile Telecommunications-2000 (IMT-2000) band from 1920 to 2170 MHz, a Global Positioning System (GPS) band from 1574.4 to 1576.4 MHz, Long Term Evolution (LTE) bands, and WiFi bands. A phase locked loop (PLL) 160 may receive control information from digital processor 110 and provide controls for VCOs 130 and 150 to generate the proper transmit and receive LO signals, respectively. In other embodiments, the receive and transmit paths may share a VCO and/or may implement separate PLLs.

A planar inductor (which is denoted as “Ind” in FIG. 1) may be used for various circuit blocks within wireless device 100. For example, the planar inductor may be used in a resonator tank circuit for VCO 112, 130 and/or 150. The inductor may also be used as a load inductor and/or a degeneration inductor for LNA 144. The inductor may also be used for any of the filters in transceiver unit 120. The inductor may also be used before and/or after mixer 128 or 148, after a driver amplifier (not shown in FIG. 1) prior to PA 134, before and/or after duplexer to matching from/to PA 134 and antenna 140, etc. The inductor used in any of these elements may have low magnetic coupling.

The inductor described herein may be implemented on an IC, an analog IC, an RFIC, a mixed-signal IC, an application specific integrated circuit (ASIC), a printed circuit board (PCB), an electronics device, etc. The inductor may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), system-in-package (SIP), etc. As indicated above, the inductor may have low magnetic coupling.

An apparatus implementing the inductor described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

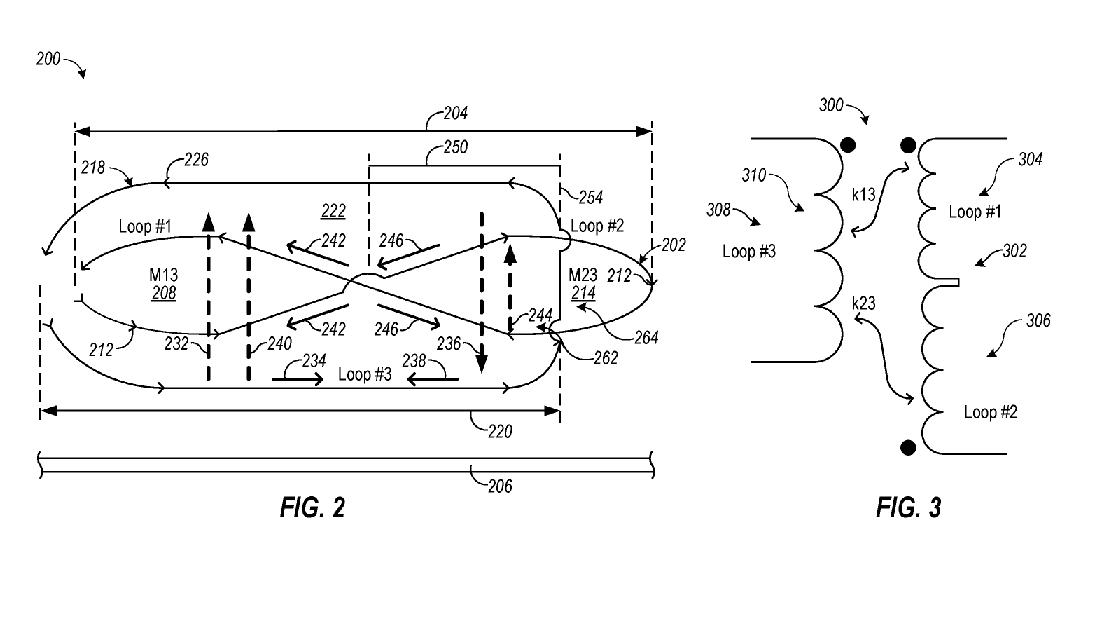

FIG. 2 shows a functional diagram of a pair of inductors 200 for a device. The device may exhibit low magnetic coupling between the inductors

A device 100 (FIG. 1) may include a pair of inductors 200 having strong near and far field isolation. The pair of inductors 200 includes a first planar inductor 202 arranged on a first area 204 of a substrate 206. The first planar inductor 202 includes a first (terminal) loop 208 arranged to produce a first magnetic flux 232 in a first direction when a conductive current 212 flows in the directions as illustrated. The first planar inductor 202 further includes a second (closed) loop 214 configured to produce a second magnetic flux 236 in a second direction when the conductive current 212 flows in the directions as illustrated.

In first planar inductor 202, the direction of the first magnetic flux 232 and the direction of the second magnetic flux 236 may be in substantially opposite directions. Furthermore, first (terminal) loop 208 and the second (closed) loop 214 of the first planar inductor 202 may be configured as a ‘figure-8’ shaped planar inductor where both loops are formed at a common reference point. A ‘figure-8’ shaped inductor may also be known as an “antisymmetric” inductor including an arrangement of a coil having a first portion of the coil rotated to create a first loop with respect to the other unrotated portion resulting in a second loop, wherein in the presence of a current through the coil, results in a first magnetic field in a first direction in the first loop and a second magnetic field in a second, substantially opposite, direction in the second loop. FIG. 2 illustrates the first planar inductor being tapped on the left side of the figure, but other tap locations may be implemented.

The pair of inductors 200 further includes a second planar inductor 218 arranged on a second area 220 of the substrate 206. The second planar inductor 218 includes a third loop 222 arranged to produce a third magnetic flux 240 in a third direction when a conductive current 226 flows in the directions as illustrated. The second planar inductor 218 is further arranged to also produce a fourth magnetic flux 244 in the third direction when the conductive current 226 flows in the directions as illustrated. The first planar inductor 202 and the second planar inductor 218 are arranged on substrate 206 so area 204 and area 220 at least partially overlap on substrate 206. FIG. 2 illustrates the second planar inductor being tapped on the left side of the figure, but other tap locations may be implemented.

In second planar inductor 218, the direction of the third magnetic flux 240 and the direction of the fourth magnetic flux 244 may be in substantially the same or parallel directions. Furthermore, third loop 222 of the second planar inductor 218 may be configured as a loop-shaped planar inductor 218 and may surround or enclose first (terminal) loop 208. The area of the second (closed) loop 214 may be divided by a portion of the third loop 222 along an axis 254 into an enclosed or internal area 262 and an external area 264. Axis 254 may be formed closer to or further from first (terminal) loop 208 to increase or decrease the low magnetic coupling between the pair of planar inductors 200 including first planar inductor 202 and second planar inductor 218.

The pair of inductors 200 further project the magnetic fields on each other which further induces currents on each other. Specifically, the first magnetic flux 232 generated in the first (terminal) loop 208 projects a magnetic field on the third loop 222. The magnetic field generates an induced current 234 in the second planar inductor 218 in the direction as illustrated. Similarly, the second magnetic flux 236 generated in the second (closed) loop 214 projects a magnetic field on the third loop 222.

The magnetic flux 236 generates an induced current 238 in the second planar inductor 218 in the direction as illustrated. Based upon the relative field strengths of the magnetic fields with respect to each other, the induced current 234 and the induced current 238 may result in an overall residual current that contributes to the low magnetic coupling of the first planar inductor 202 and the second planar inductor 218.

As stated, the pair of inductors 200 further project magnetic fields on each other which further induces currents on each other. Specifically, the third magnetic field generated in the third loop 222 projects a magnetic flux 240 on the first (terminal) loop 208. The magnetic flux 240 generates an induced current 242 in the first planar inductor 202 in the direction as illustrated.

The magnetic flux 244 generates an induced current 246 in the first planar inductor 202 in the direction as illustrated. Based upon the relative field strengths of the magnetic flux 240 and the magnetic flux 244 with respect to each other, the induced current 242 and the induced current 246 may substantially cancel or counteract each other resulting in little near and far field effects generated by the second planar inductor 218 on the first planar inductor 202.

As will be further illustrated below, the first planar inductor 202 and the second planar inductor 218 may asymmetrically overlap as illustrated in FIG. 2. Asymmetrical overlapping can create mild or low coupling which may have advantages for some specific circuit applications.

FIG. 3 shows an equivalent circuit 300 for an overlapping pair of planar inductors 200 (FIG. 2) formed on a substrate, in accordance with an aspect. The equivalent circuit 300 of the pair of planar inductors 200 includes a first winding 302 comprised of an inductance′ 304 resulting from the first (terminal) loop 208 (FIG. 2) and an inductance₂ 306 resulting from the second (closed) loop 214. The equivalent circuit 300 of the pair of planar inductors 200 further includes a second winding 308 comprised of an inductance₃ 310 resulting from the third loop 222 (FIG. 2). Loop 3 may be terminated at any point for electrical connection with other circuitry.

The inductance′ 304 and the inductance₃ 310 are related by a coupling coefficient k₁₃ resulting from resultant induced currents between the first (terminal) loop 208 of the first planar inductor 202 and the third loop 222 of the second planar inductor 218. Further, the inductance₂ 306 and the inductance₃ 310 are related by a coupling coefficient k₂₃ resulting from resultant induced currents between the second (closed) loop 214 of the first planar inductor 202 and the third loop 222 of the second planar inductor 218.

The magnitudes of coupling coefficients k₁₃ and k₂₃ may be adjusted by altering the overlapping portion 250 of the second planar inductor 218 with the first planar inductor 202 on the substrate 206. A magnetic coupling coefficient k could be minimal (even zero) to a desired coupling coefficient for circuits that may advantageously operate with magnetic coupling. Further, the polarity of the respective inductances of the windings are also illustrated in FIG. 3.

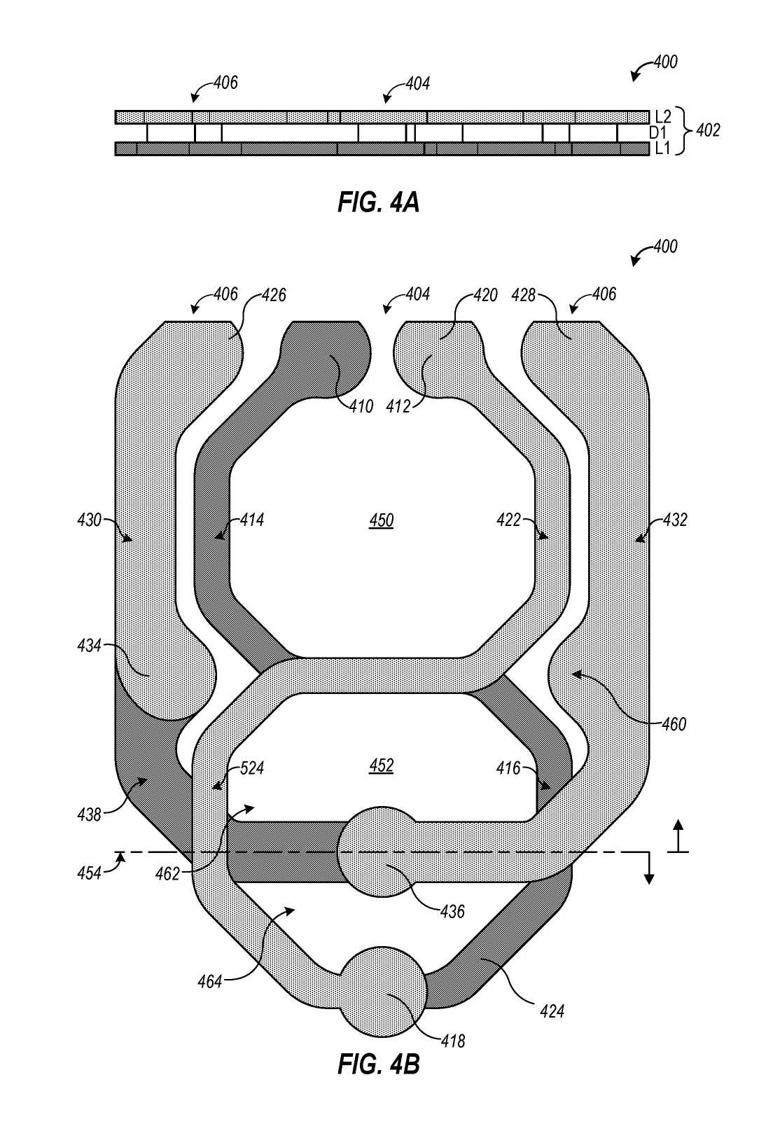

FIG. 4A shows a cross-sectional view of an exemplary layout of a pair of planar inductors 400, in accordance with an aspect. The pair of planar inductors 400 may exhibit low magnetic coupling. The pair of planar inductors 400 is formed on a substrate 402. The substrate 402 may include conductive layers L1 and L2 with dielectric layer D1 providing isolation to the conductive layers. Two or more conductive layers may be used for each planar inductor with vias electrically connecting the layers together. A first planar inductor 404 may be formed from conductive layer L1 coupling to conductive layer L2 through vias passing through dielectric layer D1. A second planar inductor 406 may be formed from conductive layer L1 coupling to conductive layer L2 through vias passing through dielectric layer D1.

FIG. 4B shows a top view of an exemplary layout of a pair of planar inductors 400, in accordance with an aspect. The pair of planar inductors 400 may exhibit low magnetic coupling. The top view is illustrated for clarity with conductive layer L2 being illustrated on top with conductive layer L1 being illustrated furthest to the back. The pair of planar inductors 400 may include the first planar inductor 404 and the second planar inductor 406.

The first planar inductor 404 may include terminals 410 and 412 located on an outer layer such as the conductive layer L1. A first portion 414 and a second portion 416 of the first planar inductor 404 also may be formed on the conductive layer L1. A via 418 may respectively connect the first portion 414 and the second portion 416 to a third portion 422 and a fourth portion 424 of the first planar inductor 404. The third portion 422 and the fourth portion 424 may be formed on the conductive layer L2. The first portion 414, the second portion 416, the third portion 422 and the fourth portion 424 collectively form the first planar inductor 404 in a ‘figure-8’ shape.

The second planar inductor 406 may include terminals 426 and 428 located on an outer layer such as the conductive layer L2. A first portion 430 and a second portion 432 of the second planar inductor 406 also may be formed on the conductive layer L2. A via 434 and via 436 may respectively connect the first portion 430 and the second portion 432 to a third portion 438 of the second planar inductor 406. The third portion 438 may be formed on the conductive layer L1. The first portion 430, the second portion 432, and the third portion 438 collectively form the second planar inductor 406 including a third loop 460 in a loop-shape. Further, other vias, such as via 420 may connect terminals and other portions to respective layers for interconnecting.

The first planar inductor 404 in a ‘figure-8’ shape includes at least a first (terminal) loop 450 and a second (closed) loop 452. First (terminal) loop 450 includes terminal 410, first portion 414, third portion 422 and terminal 412. Second (closed) loop 452 includes fourth portion 424, via 418 and second portion 416. The area of the second (closed) loop 452 is divided by a portion of the third loop 460 of the second planar inductor 406 along an axis 454 into an enclosed or internal area 462 and an external area 464. Axis 454 may be formed closer to or further from first (terminal) loop 450 to increase or decrease the low magnetic coupling between the pair of planar inductors 400 including first planar inductor 404 and second planar inductor 406.

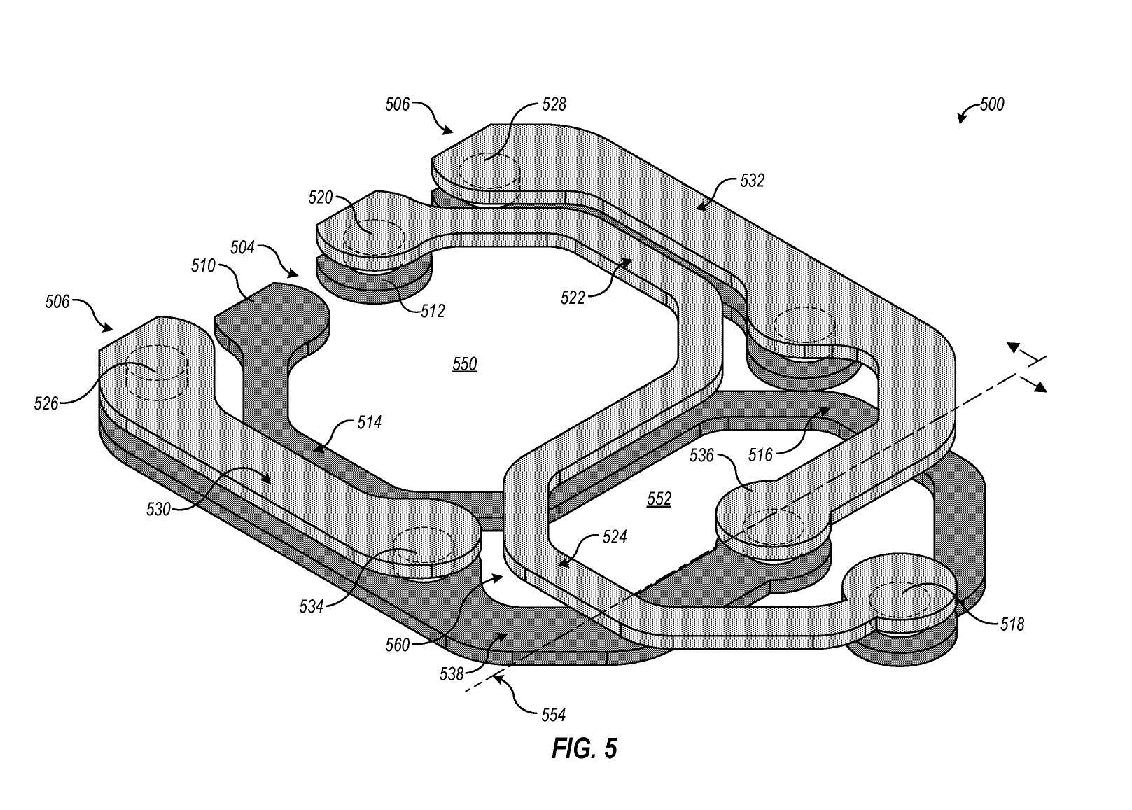

FIG. 5 shows a perspective view of an exemplary layout of a pair of planar inductors 500, in accordance with an aspect. In FIG. 5, the pair of planar inductors 500 provides a perspective view of FIG. 4B. Specifically, the conductive layer L2 is illustrated on top with conducive layer L1 being illustrated furthest to the back. The pair of planar inductors 500 may include the first planar inductor 504 and the second planar inductor 506.

The first planar inductor 504 may include terminals 510 and 512 located on an outer layer such as the conductive layer L1. A first portion 514 and a second portion 516 of the first planar inductor 504 also may be formed on the conductive layer L1. A via 518 may couple the first portion 514 and the second portion 516 to a third portion 522 and a fourth portion 524 of the first planar inductor 504. The third portion 522 and the fourth portion 524 may be formed on the conductive layer L2. The first portion 514, the second portion 516, the third portion 522 and the fourth portion 524 collectively form the first planar inductor 504 in a ‘figure-8’ shape.

The second planar inductor 506 may include terminals 526 and 528 located on an outer layer such as the conductive layer L2. A first portion 530 and a second portion 532 of the second planar inductor 506 also may be formed on the conductive layer L2. A via 534 and via 536 may respectively connect the first portion 530 and the second portion 532 to a third portion 538 of the second planar inductor 506. The third portion 538 may be formed on the conductive layer L1. The first portion 530, the second portion 532, and the third portion 538 collectively form a third loop 560 of the second planar inductor 506 in a loop-shape. Further, other vias, such as via 520 may connect terminals and other portions to respective layers for interconnecting.

The first planar inductor 504 in a ‘figure-8’ shape includes at least a first (terminal) loop 550 and a closed loop 552. First (terminal) loop 550 includes terminal 510, first portion 514, third portion 522 and terminal 512. Second (closed) loop 552 includes fourth portion 524, via 518 and second portion 516. The enclosed area of the second (closed) loop 552 is divided by portions of the second planar inductor 506 along an axis 554. Axis 554 may be formed closer to or further from first (terminal) loop 550 to increase or decrease the low magnetic coupling between the pair of planar inductors 500 including first planar inductor 504 and second planar inductor 506.

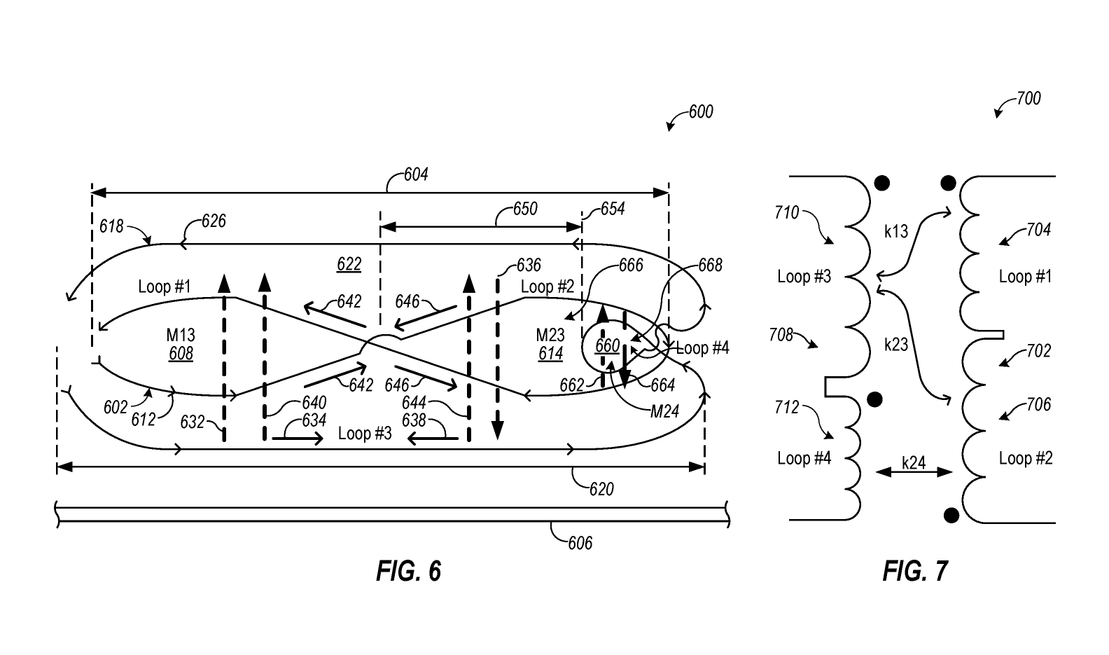

FIG. 6 shows a functional diagram of a pair of inductors 600 for a device, in accordance with another aspect. The device may exhibit low magnetic coupling between the pair of inductors 600.

A device 100 (FIG. 1) may include a pair of inductors 600 having strong near and far field isolation. The pair of inductors 600 includes a first planar inductor 602 arranged on a first area 604 of a substrate 606. The first planar inductor 602 includes a first (terminal) loop 608 arranged to produce a first magnetic flux 632 in a first direction when a conductive current 612 flows in the directions as illustrated. The first planar inductor 602 further includes a second (closed) loop 614 configured to produce a second magnetic flux 636 in a second direction when the conductive current 612 flows in the directions as illustrated.

In first planar inductor 602, the direction of the first magnetic flux 632 and the direction of the second magnetic flux 636 may be in substantially opposite directions. Furthermore, first (terminal) loop 608 and the second (closed) loop 614 of the first planar inductor 602 may be configured as a ‘figure-8’ shaped planar inductor where both loops are formed at a common reference point. FIG. 6 illustrates the first planar inductor 602 being tapped on the left side of the figure, but other tap locations may be implemented.

The pair of inductors 600 further includes a second planar inductor 618 arranged on a second area 620 of the substrate 606. The second planar inductor 618 includes a third loop 622 arranged to produce a third magnetic flux 640 in a third direction when a conductive current 626 flows in the directions as illustrated. The second planar inductor 618 is further arranged to also produce a fourth magnetic flux 644 in the third direction when the conductive current 626 flows in the directions as illustrated. The first planar inductor 602 and the second planar inductor 618 are arranged on substrate 606 so area 604 and area 620 at least partially overlap on substrate 606. FIG. 6 illustrates the second planar inductor 618 being tapped on the left side of the figure, but other tap locations may be implemented.

In second planar inductor 618, the direction of the third magnetic flux 640 and the direction of the fourth magnetic flux 644 may be in substantially the same or parallel directions. Furthermore, the third loop 622 of the second planar inductor 618 may be configured as a loop-shaped planar inductor 618 and may surround or enclose first (terminal) loop 608.

The second planar inductor 618 further includes a fourth loop 660 arranged to produce a fifth magnetic flux 662 in a fifth direction when a conductive current 626 flows in the directions as illustrated. The first planar inductor 602 further produces a sixth magnetic flux 664 in a sixth direction when the conductive current 612 flows in the directions as illustrated. The first planar inductor 602 and the second planar inductor 618 are arranged on substrate 606 so area 604 and area 620 at least partially overlap on substrate 606. Furthermore, the fourth loop 660 is configured to be substantially within the second loop 614. The enclosed area of the second (closed) loop 614 may be divided by the fourth loop 660 of the second planar inductor 618 along an axis 654 into a fourth loop excluded area 666 and a fourth loop enclosed area 668. Axis 654 may be formed closer to or further from first (terminal) loop 608 to increase or decrease the low magnetic coupling between the pair of planar inductors 600 including first planar inductor 602 and second planar inductor 618. Stated another way, the fourth loop 660 is enclosed by the third loop 622 and the second (closed) loop 614.

In second planar inductor 618, the direction of the third magnetic flux 640 and the direction of the fourth magnetic flux 644 may be in substantially the same or parallel directions. Furthermore, third loop 622 of the second planar inductor 618 may be configured as a loop-shaped planar inductor.

The pair of inductors 600 further project the magnetic fields on each other which further induces currents on each other. Specifically, the first magnetic flux 632 generated in the first (terminal) loop 608 projects a magnetic field on the third loop 622. The magnetic field generates an induced current 634 in the second planar inductor 618 in the direction as illustrated. Similarly, the second magnetic flux 636 and 664 generated in the second (closed) loop 614 projects a magnetic field on the third loop 622.

The magnetic flux 636 and 664 generates an induced current 638 in the second planar inductor 618 in the direction as illustrated. Based upon the relative field strengths of the magnetic fields with respect to each other, the induced current 634 and the induced current 638 may result in an overall residual current that contributes to the low magnetic coupling of the first planar inductor 602 and the second planar inductor 618.

As stated, the pair of inductors 600 further project magnetic fields on each other which further induces currents on each other. Specifically, the third magnetic field generated in the third loop 622 projects a third magnetic flux 640 on the first (terminal) loop 608. The third magnetic flux 640 generates an induced current 642 in the first planar inductor 602 in the direction as illustrated. Similarly, the fourth magnetic field generated in the third loop 622 projects a fourth magnetic flux 644 on the second (closed) loop 614. Additionally, the fifth magnetic field generated in the fourth loop 660 projects a fifth magnetic flux 662 on the second (closed) loop 614.

The fourth and the fifth magnetic flux 644 and 662 generate an induced current 646 in the first planar inductor 602 in the direction as illustrated. Based upon the relative field strengths of the third magnetic flux 640 and the sum of the fourth and the fifth magnetic flux 644 and 662 with respect to each other, the induced current 642 and the induced current 646 may substantially cancel or counteract each other resulting in little near and far field effects generated by the second planar inductor 618 on the first planar inductor 602.

As will be further illustrated below, the first planar inductor 602 and the second planar inductor 618 may asymmetrically overlap as illustrated in FIG. 6. Asymmetrical overlapping can create mild or low magnetic coupling which may have advantages for some specific circuit applications.

FIG. 7 shows an equivalent circuit 700 for an overlapping pair of planar inductors 600 (FIG. 6) formed on a substrate, in accordance with another aspect. The equivalent circuit 700 of the pair of planar inductors 600 includes a first winding 702 comprised of an inductance′ 704 resulting from the first (terminal) loop 608 (FIG. 6) and an inductance₂ 706 resulting from the second (closed) loop 614. The equivalent circuit 700 of the pair of planar inductors 600 further includes a second winding 708 comprised of an inductance₃ 710 resulting from the third loop 622 (FIG. 6) and an inductance₄ 712 resulting from the fourth loop 660 of the second planar inductor 618.

The inductance′ 704 and the inductance₃ 710 are related by a coupling coefficient k₁₃ resulting from resultant induced currents between the first (terminal) loop 608 of the first planar inductor 602 and the third loop 622 of the second planar inductor 618. Further, the inductance₂ 706 and the inductance₃ 710 are related by a coupling coefficient k₂₃ resulting from resultant induced currents between the second (closed) loop 614 of the first planar inductor 602 and the third loop 622 of the second planar inductor 618. Yet further, the inductance₂ 706 and the inductance₄ 712 are related by a coupling coefficient k₂₄ resulting from resultant induced currents between the second (closed) loop 614 of the first planar inductor 602 and the fourth loop 660 of the second planar inductor 618.

The magnitudes of coupling coefficients k₁₃, k₂₃ and k₂₄ may be adjusted by altering the overlapping portion 650 of the second planar inductor 618 with the first planar inductor 602 on the substrate 606. A magnetic coupling coefficient k could be minimal (even zero) to a desired coupling coefficient for circuits that may advantageously operate with magnetic coupling. Further, the polarity of the respective inductances of the windings are also illustrated in FIG. 7.

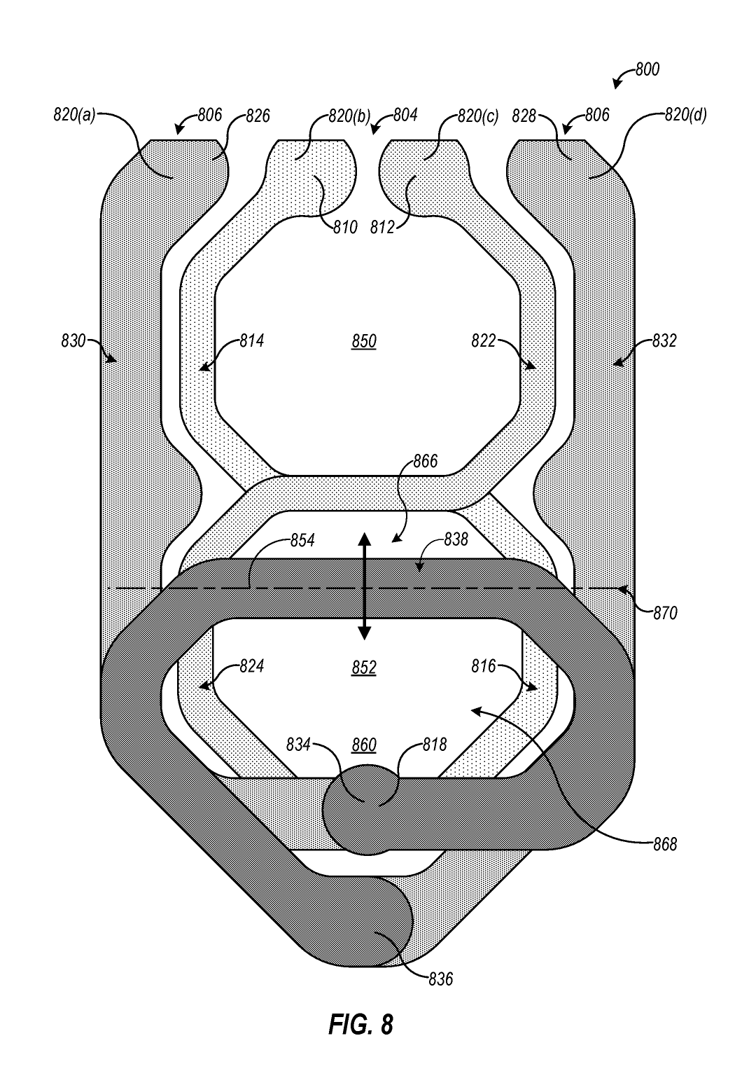

FIG. 8 shows a top view of an exemplary layout of a pair of planar inductors 800, in accordance with another aspect. The pair of inductors 800 may exhibit low magnetic coupling. The top view is illustrated for clarity with conductive layer L4 being illustrated on top with conductive layer L1 being illustrated furthest to the back. The pair of planar inductors 800 may include the first planar inductor 804 and the second planar inductor 806. By way of example and not limitation, first planar inductor 804 is formed with conductive layers L1 and L2 and second planar inductor 806 is formed with conductive layers L3 and L4.

The first planar inductor 804 may include terminals 810 and 812 located on a layer such as the conductive layers L1 and L2. A first portion 814 and a second portion 816 of the first planar inductor 804 also may be formed on the conductive layer L1. A via 818 may respectively connect the first portion 814 and the second portion 816 to a third portion 822 and a fourth portion 824 of the first planar inductor 804. The third portion 822 and the fourth portion 824 may be formed on the conductive layer L2. The first portion 814, the second portion 816, the third portion 822 and the fourth portion 824 collectively form the first planar inductor 804 in a ‘figure-8’ shape.

The second planar inductor 806 may include terminals 826 and 828 located on layers such as the conductive layers L3 and L4. A first portion 830 and a second portion 832 of the second planar inductor 806 also may be formed on the conductive layer L3. A via 818 and via 836 may respectively connect the first portion 830 and the second portion 832 to a third portion 838 of the second planar inductor 806. The third portion 838 may be formed on the conductive layer L4. The first portion 830, the second portion 832, and the third portion 838 collectively form the second planar inductor 806 in a loop-shape with a fourth (internal) loop 860. Further, other vias, such as via 820 may connect terminals and other portions to respective layers for interconnecting.

The first planar inductor 804 in a ‘figure-8’ shape includes at least a first (terminal) loop 850 and a second (closed) loop 852. First (terminal) loop 850 includes terminal 810, first portion 814, third portion 822 and terminal 812. Second (closed) loop 852 includes fourth portion 824, via 818 and second portion 816. The enclosed area of the second (closed) loop 852 may be divided by the fourth loop 860 of the second planar inductor 806 along an axis 854 into a fourth loop excluded area 866 and a fourth loop enclosed area 868. Axis 854 may be formed closer to or further from first (terminal) loop 850 to increase or decrease the low magnetic coupling between the pair of planar inductors 800 including first planar inductor 804 and second planar inductor 806. Stated another way, the fourth loop 860 is enclosed by the third loop 870 and the second (closed) loop 852.

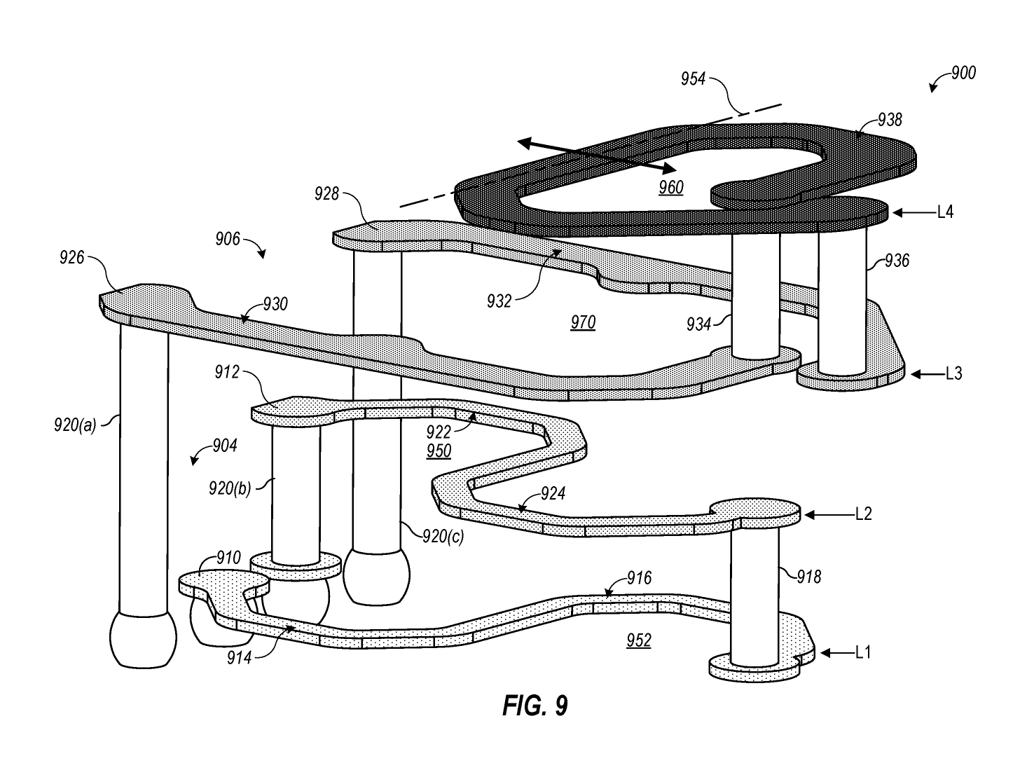

FIG. 9 shows a perspective view of an exemplary layout of a pair of planar inductors 900, in accordance with another aspect. In FIG. 9, the pair of planar inductors 900 provides a perspective view of FIG. 8. Specifically, the conductive layer L4 is illustrated on top with conducive layer L1 being illustrated furthest to the bottom. The pair of planar inductors 900 may include the first planar inductor 904 and the second planar inductor 906.

The first planar inductor 904 may include terminals 910 and 912 located on an outer layer such as the conductive layer L1. A first portion 914 and a second portion 916 of the first planar inductor 904 also may be formed on the conductive layer L1. A via 918 may connect the first portion 914 and the second portion 916 to a third portion 922 and a fourth portion 924 of the first planar inductor 904. The third portion 922 and the fourth portion 924 may be formed on the conductive layer L2. The first portion 914, the second portion 916, the third portion 922 and the fourth portion 924 collectively form the first planar inductor 904 in a ‘figure-8’ shape.

The second planar inductor 906 may include terminals 926 and 928 located on another layer such as the conductive layer L3. A first portion 930 and a second portion 932 of the second planar inductor 906 also may be formed on the conductive layer L3. A via 934 and via 936 may respectively connect the first portion 930 and the second portion 932 to a third portion 938 of the second planar inductor 906. The third portion 938 may be formed on the conductive layer L4. The first portion 930 and second portion 932 collectively form a third loop 970. Third loop 970 and the third portion 938 collectively form the second planar inductor 906 in a loop-shape with a fourth (internal) loop 960. Further, other vias, such as via 920 may connect terminals and other portions to respective layers for interconnecting.

The first planar inductor 904 in a ‘figure-8’ shape includes at least a first (terminal) loop 950 and a second (closed) loop 952. First (terminal) loop 950 includes terminal 910, first portion 914, third portion 922 and terminal 912. Second (closed) loop 952 includes fourth portion 924, via 918 and second portion 916. The enclosed area of the second (closed) loop 952 is divided by portions of the second planar inductor 906 along an axis 954. Axis 954 may be formed closer to or further from first (terminal) loop 950 to increase or decrease the low magnetic coupling between the pair of planar inductors 900 including first planar inductor 904 and second planar inductor 906.

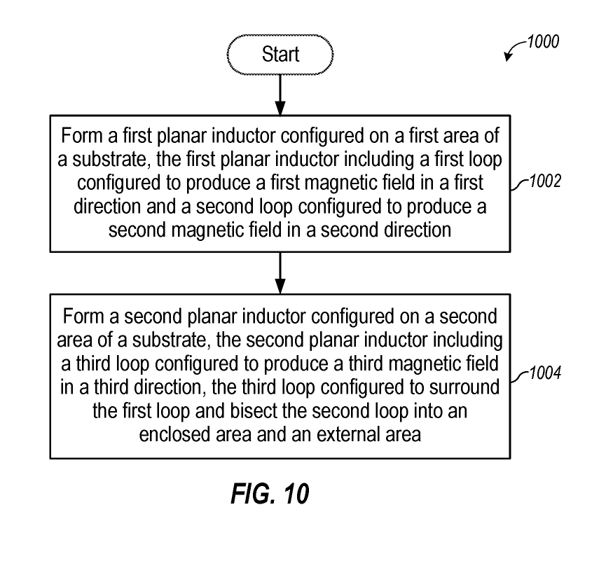

FIG. 10 is a flowchart illustrating a method 1000, in accordance with one or more exemplary embodiments. Method 1000 may include forming, in a step 1002, a first planar inductor configured on a first area of a substrate. The first planar inductor including a first loop configured to produce a first magnetic field in a first direction and a second loop configured to produce a second magnetic field in a second direction. Method 1000 may further include forming, in a step 1004, a second planar inductor configured on a second area of the substrate, the second planar inductor including a third loop configured to produce a third magnetic field in a third direction, the third loop configured to surround the first loop and divide the second loop into an enclosed area and an external area.

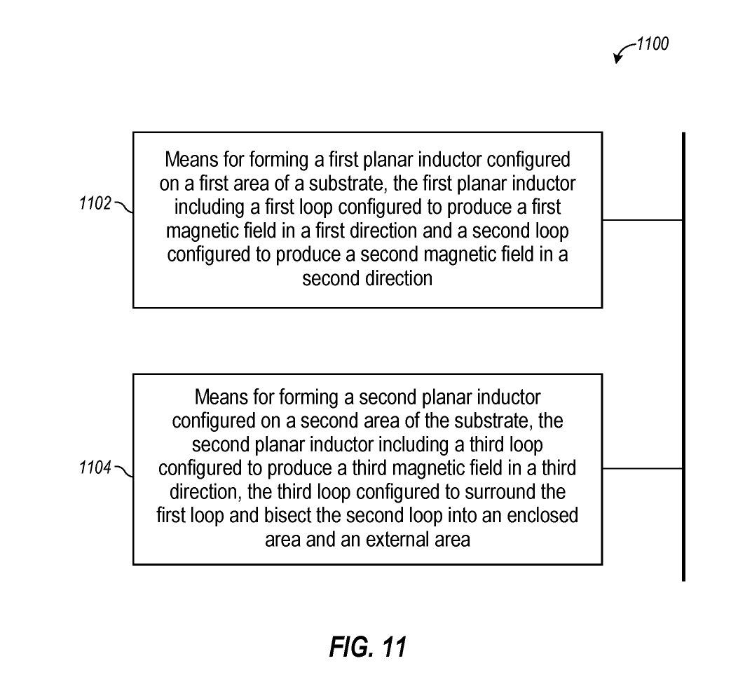

FIG. 11 shows an exemplary embodiment of device 1100. In one exemplary embodiment, device 1100 is implemented by one or more modules configured to provide the functions as described herein. For example, in an aspect, each module comprises hardware and/or hardware executing software.

Device 1100 comprises means 1102 for forming a first planar inductor configured on a first area of a substrate, the first planar inductor including a first loop configured to produce a first magnetic field in a first direction and a second loop configured to produce a second magnetic field in a second direction.

Device 1100 also comprises a means 1104 for forming a second planar inductor configured on a second area of the substrate, the second planar inductor including a third loop configured to produce a third magnetic field in a third direction, the third loop configured to surround the first loop and divide the second loop into an enclosed area and an external area.

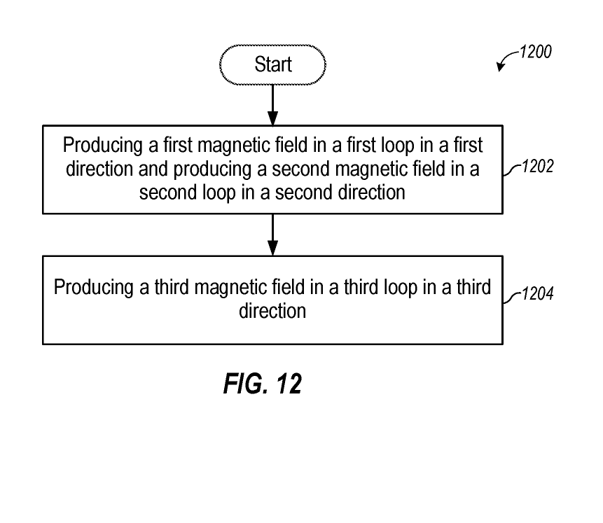

FIG. 12 is a flowchart illustrating a method, in accordance with one or more exemplary embodiments. In one exemplary embodiment, a method 1200 may include producing, in a step 1202, a first magnetic field in a first loop in a first direction and producing a second magnetic field in a second loop in a second direction. Method 1200 may further include producing, in a step 1204, a third magnetic field in a third loop in a third direction. The third direction may be substantially aligned with either the first or second directions. The third loop may surround or enclose the first loop and bisect the second loop. Bisection of the second loop does not require that the second loop be divided into two equal portions, but certain embodiments may be configured in such implementation.

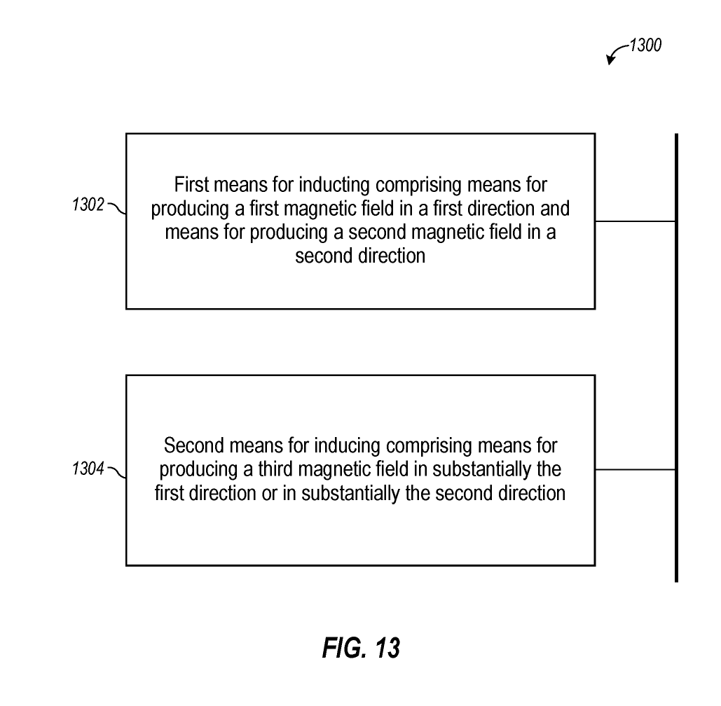

FIG. 13 shows a functional diagram of an apparatus 1300 including a pair of inductors for a device, in accordance with an embodiment. The device may exhibit low magnetic coupling between the pair of inductors. In one exemplary embodiment, an apparatus 1300 is implemented by one or more modules configured to provide the functions as described herein. For example, in an aspect, each module comprise hardware and/or hardware executing software.

The apparatus 1300 comprise a first means 1302 for inducting comprising means for producing a first magnetic field in a first direction and means for producing a second magnetic field in a second direction. The apparatus 1300 further comprises a second means 1304 for inducing comprising means for producing a third magnetic field in substantially the first direction or in substantially the second direction. The apparatus 1300 may further be configured such that the means for producing the third magnetic field surrounds or encloses the means for producing the first magnetic field and bisects the means for producing the second magnetic field.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions are not a departures from the scope of the exemplary embodiments of the disclosure.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise non-transitory media such as RAM, ROM, EEPROM, CD-ROM or other optical disk storage, magnetic disk storage or other magnetic storage devices, or may comprise any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above are also be included within the scope of computer-readable media.

The previous description of the disclosed exemplary embodiments is provided to enable any person skilled in the art to make or use the present disclosure. Various modifications to these exemplary embodiments will be readily apparent to those skilled in the art, and the generic principles defined herein may be applied to other embodiments without departing from the spirit or scope of the disclosure. Thus, the present disclosure is not intended to be limited to the exemplary embodiments shown herein but is to be accorded the widest scope consistent with the principles and novel features disclosed herein.

What is claimed is:

1. A device, comprising:
a first planar inductor configured on a first area of a substrate, the first planar inductor including a first loop and a second loop arranged in a figure-8 configuration; and
a second planar inductor configured on a second area of the substrate, the second planar inductor including a third loop surrounding the first loop and dividing the second loop into an enclosed area and an external area.

2. The device of claim 1, wherein a ratio of the enclosed area and the external area determines a magnitude of magnetic coupling between the first planar inductor and the second planar inductor.

3. The device of claim 1, wherein the second planar inductor further includes a fourth loop electrically connected to the third loop.

4. The device of claim 3, wherein the fourth loop is enclosed by the third loop.

5. The device of claim 3, wherein the fourth loop is enclosed by the second loop.

6. The device of claim 1, wherein the first planar inductor and the second planar inductor are configured to have a non-zero magnetic coupling there between.

7. The device of claim 1, wherein the first loop is configured to produce a first magnetic field in a first direction and the second loop is configured to produce a second magnetic field in a second direction substantially opposite the first direction.

8. A method, comprising:
producing a first magnetic field in a first conductive loop in a first direction and producing a second magnetic field in a second conductive loop in a second direction; and
producing a third magnetic field in a third conductive loop in a third direction, the third conductive loop surrounding or enclosing the first conductive loop and bisecting the second conductive loop.

9. The method of claim 8, wherein the first direction and the second direction are substantially opposite.

10. The method of claim 8, wherein the first conductive loop and the second conductive loop are formed on a first layer and a second layer of a substrate respectively, and the third conductive loop is formed on the first layer and the second layer of the substrate.

11. The method of claim 8, wherein the third conductive loop divides the second conductive loop into an enclosed area and an external area.

12. The method of claim 8, further comprising processing a radio frequency signal based at least in part on the producing the first, second, and third magnetic fields.

13. The method of claim 12, wherein the processing comprises filtering or amplifying the radio frequency signal.

14. The method of claim 8, wherein the first conductive loop and the second conductive loop comprise a first planar inductor and the third conductive loop comprises a second planar inductor.

15. An apparatus, comprising:
first means for inducting comprising means for producing a first magnetic field in a first direction and means for producing a second magnetic field in a second direction; and
second means for inducing comprising means for producing a third magnetic field in substantially the first direction or in substantially the second direction,
wherein the means for producing the third magnetic field surrounds or encloses the means for producing the first magnetic field and bisects the means for producing the second magnetic field.

16. The apparatus of claim 15, wherein the first direction and the second direction are substantially opposite.

17. The apparatus of claim 15, wherein the first means for inducting is formed on a first layer of a substrate and the second means for inducting is formed on a second layer of the substrate.

18. The apparatus of claim 15, the means for producing the third magnetic field divides the means for producing the second magnetic field into an enclosed area and an external area.

19. The apparatus of claim 15, wherein the apparatus is included in a device at least partially configured to process radio frequency signals.

20. The apparatus of claim 15, wherein the first means for inducting comprises a first planar inductor and the second means for inducting comprises a second planar inductor.
